(19) United States
(12) Patent Application Publication
(10) Pub. No.: US 2015/0277176 A1
(43) Pub. Date: Oct. 1, 2015

(54) DISPLAY APPARATUS

(71) Applicant: Samsung Display Co., Ltd., Yongin-City (KR)

(72) Inventors: Dongwuuk SEO, Asan-Si (KR); Taewoo KIM, Asan-Si (KR); Juhyeon BAEK, Asan-Si (KR); Minhee SON, Anyang-Si (KR); Hyejung LEE, Bucheon-Si (KR); Jiyoung JEONG, Cheonan-Si (KR)

(21) Appl. No.: 14/508,604

(22) Filed: Oct. 7, 2014

(30) Foreign Application Priority Data
Mar. 25, 2014 (KR) 10-2014-0034876

(51) Int. Cl. G02F 1/1339; G02F 1/1335; G02F 1/1362; H01L 27/12; G02F 1/1368

(52) U.S. Cl. CPC G02F 1/13394; H01L 27/124; G02F 1/1368; G02F 1/136286; G02F 1/133512; G02F 1/133514; G02F 2001/133357

(57) ABSTRACT

A display apparatus includes a first substrate, a second substrate, a liquid crystal layer, and a spacer. The first substrate includes a gate line extending in a first direction, a data line extending in a second direction substantially perpendicular to the first direction, and a gate electrode branched from the gate line. The spacer is disposed on the second substrate and protrudes toward the first substrate and includes a first spacer and a second spacer with different heights that are connected to each other. The first spacer makes contact with the first substrate and the second substrate, and the second spacer makes contact with the second substrate and is spaced apart from the first substrate.

### CROSS-REFERENCE TO RELATED APPLICATION

This U.S. non-provisional patent application claims priority under 35 U.S.C. §119 from Korean Patent Application No. 10-2014-0034876, filed on Mar. 25, 2014, and all the benefits accruing therefrom, the contents of which are herein incorporated by reference in their entirety.

### BACKGROUND

1. Technical Field

Embodiments of the present disclosure are directed to a display apparatus. More particularly, embodiments of the present disclosure are directed to a display apparatus having an improved durability.

2. Discussion of the Related Art

A liquid crystal display is a thin and flat display device that includes two substrates and a liquid crystal layer interposed between the two substrates. A liquid crystal display includes a backlight unit to generate light. The liquid crystal layer includes liquid crystal molecules.

A liquid crystal display also includes a spacer disposed between the two substrates. The spacer maintains a gap between the two substrates and absorbs external impacts.

When a touch event occurs on a lower substrate of the two substrates, the position of the spacer changes due to the touch event. After the touch event has ended, the position of the spacer returns to its original position.

Due to the change in the spacer position, an alignment layer disposed on the lower substrate may be damaged. The damaged alignment layer may not not control the liquid crystal molecules. As a result, light leakage may occur in an area that corresponds to the damaged alignment layer.

In addition, when the position of the spacer does not return to its original position, the liquid crystal molecules adjacent to the spacer may not be controlled. Consequently, light leakage may occur around the spacer.

### SUMMARY

Embodiments of the present disclosure can provide a display apparatus having an improved durability.

Embodiments of the inventive concept provide a display apparatus including a first substrate, a second substrate, and a spacer. The first substrate includes a gate line, a data line, and a gate electrode. The gate line extends in a first direction, the data line extends in a second direction substantially perpendicular to the first direction, and the gate electrode is branched from the gate line. The second substrate faces the first substrate. The spacer is disposed on the second substrate and protrudes toward the first substrate, and includes a first spacer and a second spacer connected to each other that have different heights. The first spacer makes contact with the first substrate and the second substrate, and the second spacer makes contact with the second substrate and is spaced above the first substrate.

The first substrate further includes a first base substrate, a pixel electrode disposed on the first base substrate, a common electrode that includes a plurality of slits, at least a portion of which overlaps the pixel electrode, a thin film transistor electrically connected to the gate line and the data line to apply a signal to the pixel electrode, and a gate spacer part disposed on a same layer as the gate electrode that branches from the gate line and is spaced apart from the gate electrode and the thin film transistor. at least a portion of the spacer overlaps with the gate spacer part.

The thin film transistor includes the gate electrode disposed on the first base substrate, a semiconductor pattern disposed on the gate electrode, a source electrode disposed on the semiconductor pattern that partially overlaps the gate electrode, and a drain electrode spaced apart from the source electrode, connected to the pixel electrode through a contact hole, that partially overlaps the gate electrode. The gate spacer part is spaced apart from the contact hole.

The first substrate further includes a display area in which an image is displayed and a non-display area in which no image is displayed. The spacer overlaps the non-display area.

The first substrate further includes a source spacer part of which at least a portion thereof overlaps the gate spacer part. The source spacer part is disposed on a same layer as the source electrode.

The second substrate includes a second base substrate, a black matrix disposed on the second base substrate, a color filter disposed on the second base substrate to display a color image, and a planarization layer disposed on the black matrix and the color filter. The black matrix overlaps the gate line and the data line. The spacer is disposed on the planarization layer and overlaps the black matrix.

A plurality of spacers are provided.

The first substrate further include a plurality of gate lines and a plurality of data lines, and a plurality of pixel areas defined by the gate lines and the data lines. Each pixel area includes a red pixel area displaying a red color, a green pixel area displaying a green color, and a blue pixel area displaying a blue color, and the spacers are disposed in the red pixel area and the blue pixel area.

The first spacer has a height greater than a height of the second spacer.

The spacer includes an upper surface in contact with a lower surface of the second substrate and a lower surface that faces an upper surface of the first substrate. The lower surface has a shape defined by a first circle and a second circle that partially overlaps the first circle.

The lower surface includes a first lower surface corresponding to a lower surface of the first spacer and a second lower surface corresponding to a lower surface of the second spacer. The first lower surface has a circular shape, the second lower surface has a shape corresponding to a portion of a circle, and the first lower surface has an area greater than an area of the second lower surface.

Embodiments of the inventive concept provide a display apparatus that includes a first substrate, a second substrate, and a plurality of spacers. The first substrate includes a plurality of gate lines extending in a first direction, and a plurality of data lines extending in a second direction substantially perpendicular to the first direction. The second substrate faces the first substrate. The plurality of spacers are disposed on the second substrate and protrude toward the first substrate. Each spacer includes a first spacer and a second spacer connected to each other; an upper surface in contact with a lower surface of the second substrate; and a lower surface that faces an upper surface of the first substrate. The lower surface has a shape defined by a first circle and a second circle that partially overlaps the first circle.

The first substrate further includes a first base substrate, a pixel electrode, a common electrode, a thin film transistor, a gate spacer part, and a source spacer part. The pixel electrode is disposed on the first base substrate. The common electrode includes a plurality of slits, and at least a portion of the common electrode overlaps the pixel electrode. The thin film transistor is electrically connected to the gate line and the data line to apply a signal to the pixel electrode. The gate spacer part is disposed on a same layer as the gate line and is spaced apart from the gate line and the thin film transistor, and at least a portion of the spacer overlaps with the gate spacer part. At least a portion of the source spacer part overlaps the gate spacer part, and the source spacer part is disposed on a same layer as the data line.

The display apparatus further includes a liquid crystal layer interposed between the first substrate and the second substrate.

The first substrate further includes a display area in which an image is displayed and a non-display area in which no image is displayed. Each spacer overlaps the non-display area.

The second substrate includes a second base substrate, a black matrix, a color filter, and a planarization layer. The black matrix is disposed on the second base substrate and overlaps the gate line and the data line. The color filter is disposed on the second base substrate to display color images. The planarization layer is disposed on the black matrix and the color filter. Each spacer is disposed on the planarization layer and overlaps the black matrix.

The first spacer has a height greater than a height of the second spacer and makes contact with the first substrate and the second substrate. The second spacer makes contact with the second substrate and is spaced above the first substrate.

The lower surface includes a first lower surface corresponding to a lower surface of the first spacer; and a second lower surface corresponding to a lower surface of the second spacer. The first lower surface has a circular shape, the second lower surface has a shape corresponding to a portion of a circle, and the first lower surface has an area greater than an area of the second lower surface.

The display apparatus further includes a plurality of pixel areas defined by the gate lines and the data lines. Each pixel area comprises a red pixel area to display a red color, a green pixel area to display a green color, and a blue pixel area to display a blue color. The spacer is disposed in the red pixel area and the blue pixel area.

According to the above, the durability of the display apparatus may be improved.

### BRIEF DESCRIPTION OF THE DRAWINGS

FIG. 1 is a perspective view that shows a display apparatus according to an exemplary embodiment of the present disclosure.

FIG. 2 is a plan view that shows a pixel area according to an exemplary embodiment of the present disclosure.

FIG. 3 is a cross-sectional view taken along a line I-I′ of FIG. 2.

FIG. 4 is a plan view that shows a pixel area according to an exemplary embodiment of the present disclosure.

FIG. 5A is a perspective view that shows a spacer according to an exemplary embodiment of the present disclosure.

FIG. 5B is a plan view that shows a lower surface of the spacer.

### DETAILED DESCRIPTION

It will be understood that when an element or layer is referred to as being “on”, “connected to” or “coupled to” another element or layer, it can be directly on, connected or coupled to the other element or layer or intervening elements or layers may be present.

Hereinafter, the present disclosure will be explained in detail with reference to the accompanying drawings.

In the following description, a liquid crystal display will be described as a display apparatus, but the display apparatus should not be limited to the liquid crystal display. For example, the display apparatus may be a plasma display apparatus, an electrophoretic display apparatus, or an electrowetting display apparatus.

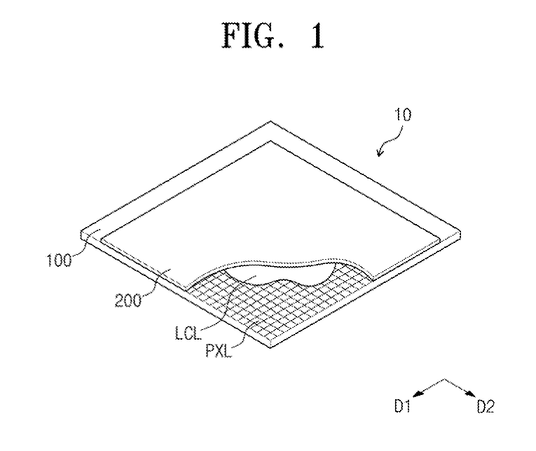

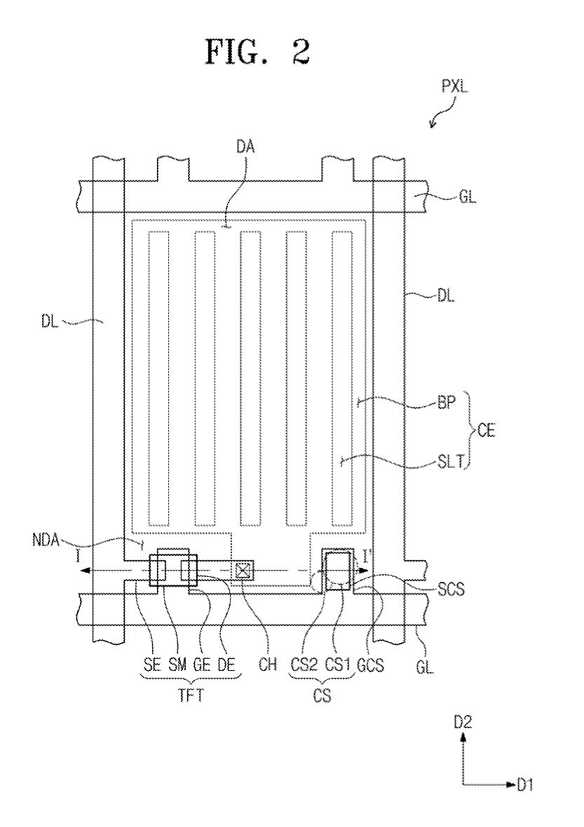

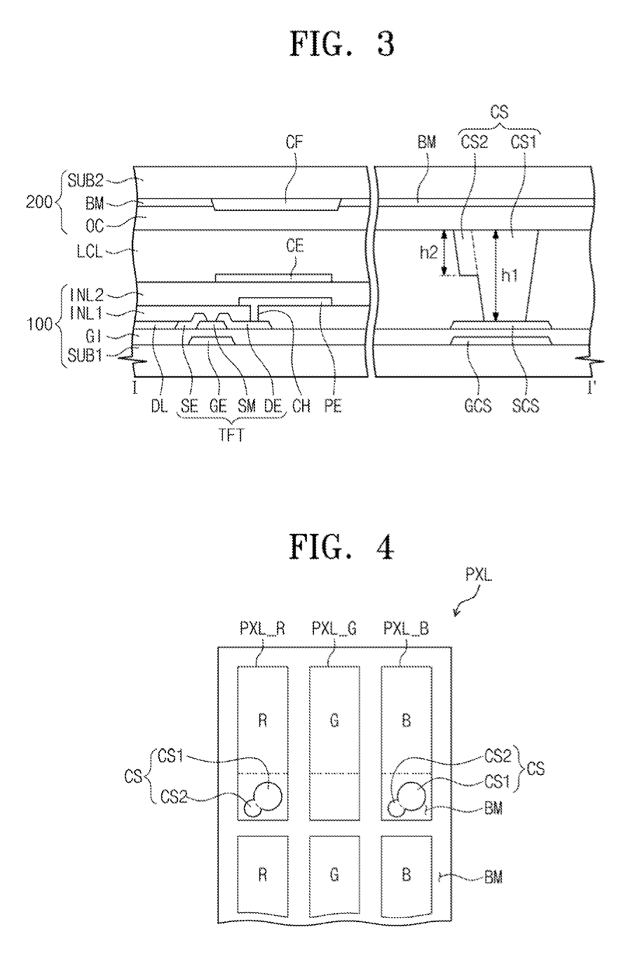

FIG. 1 is a perspective view that shows a display apparatus according to an exemplary embodiment of the present disclosure, FIG. 2 is a plan view that shows a pixel area according to an exemplary embodiment of the present disclosure, and FIG. 3 is a cross-sectional view taken along a line I-It of FIG. 2. FIG. 2 shows the pixel area of a display apparatus driven in a horizontal switching mode as a representative example, however, it should not be limited to a horizontal switching mode. That is, the pixel area of the display apparatus may be driven in a vertical alignment mode or a twisted nematic mode.

Referring to FIGS. 1 to 3, a display apparatus 10 includes a first substrate 100, a second substrate 200 that faces the first substrate 100, a liquid crystal layer LCL interposed between the first substrate 100 and the second substrate 200, and a spacer CS interposed between the first substrate 100 and the second substrate 200.

The first substrate 100 includes a display area DA and a non-display area NDA.

The first substrate 100 includes a plurality of pixel areas PXL. The pixel areas PXL may be defined by gate lines GL and data lines DL. Each pixel area PXL defined in the first substrate 100 includes at least one thin film transistor TFT and a pixel electrode PE to drive liquid crystal molecules of the liquid crystal layer LCL.

The first substrate 100 includes a first base substrate SUB 1, the thin film transistor TFT, the pixel electrode PE, and a common electrode CE.

The first base substrate SUB1 may be a transparent insulating substrate, such as a plastic substrate, a glass substrate, a quartz substrate, etc.

The gate lines GL and the data lines DL are disposed on the first base substrate SUB1. The gate lines GL extend in a first direction D1 on the first base substrate SUB1. The data lines DL extend in a second direction D2 substantially perpendicular to the first direction D1 to cross the gate lines GL, and a gate insulating layer GI is disposed between the gate lines GL and the data lines DL.

For the convenience of explanation, hereinafter, reference will be made to one or two gate lines GL and one or two data lines DL to describe an exemplary pixel area PXL since each pixel area PXL has the same structure and function.

The thin film transistor TFT includes a gate electrode GE, a semiconductor pattern SM, a source electrode SE, and a drain electrode DE.

The gate electrode GE branches from the gate line GL or is provided at a portion of the gate line GL. The gate electrode GE may include a metal. The gate electrode GE may have a multi-layer structure. The gate electrode GE may include one or more of nickel, chromium, molybdenum, aluminum, titanium, copper, tungsten, or alloys thereof.

The gate insulating layer GI is disposed on the gate electrode GE. The gate insulating layer GI may be disposed over an entire surface of the first base substrate SUB1 to cover the gate line GL and the gate electrode GE.

The semiconductor pattern SM is disposed on the gate insulating layer GI. The semiconductor pattern SM is disposed over the gate electrode GE and the gate insulating layer GI is disposed between the gate electrode GE and the semiconductor pattern SM. Thus, a portion of the semiconductor pattern SM overlaps the gate electrode GE.

The source electrode SE branches from the data line DL. A portion of the source electrode SE overlaps the gate electrode GE.

The drain electrode DE is spaced apart from the source electrode SE and the semiconductor pattern SM is disposed between the drain electrode DE and the source electrode SE. A portion of the drain electrode DE overlaps with the gate electrode GE.

The source electrode SE and the drain electrode DE may have a multi-layer structure. The source electrode SE and the drain electrode DE may include one or more of nickel, chromium, molybdenum, aluminum, titanium, copper, tungsten, or alloys thereof.

A first insulating layer INLI is disposed on the first substrate to cover the data line DL, the thin film transistor TFT, and the gate insulator GI. The first insulating layer INL1 has a multi-layer structure, e.g., a double-layer structure of an organic layer and/or an inorganic layer.

The pixel electrode PE is disposed on the first insulating layer INL1. The pixel electrode PE is connected to the drain electrode DE through a contact hole CH disposed in the first insulating layer INL1. The pixel electrode PE includes a transparent conductive material. The transparent conductive material may include a transparent conductive oxide, such as indium tin oxide (ITO), indium zinc oxide (IZO), indium tin zinc oxide (ITZO), etc. The pixel electrode PE may be formed through various methods, such as a photolithography process.

The common electrode CE is disposed above the pixel electrode PE to form an electric field in cooperation with the pixel electrode PE to drive the liquid crystal molecules of the liquid crystal layer LCL.

Referring to FIG. 2, the common electrode CE includes a plurality of slits SLT and a plurality of branch portions BP alternately arranged with the slits SLT.

Referring to FIGS. 1 to 3, the common electrode CE is disposed on a second insulating layer INL2 disposed on the pixel electrode PE and the first insulating layer INL1. The second insulating layer INL2 has a multi-layer structure that may include an organic layer and/or an inorganic layer. The second insulating layer INL2 may protect the thin film transistor TFT and may planarize an upper surface of the first base substrate SUB 1 on which the thin film transistor TFT is disposed.

The common electrode CE includes a transparent conductive material. The transparent conductive material may include a conductive metal oxide, such as ITO, IZO, ITZO, etc. The common electrode CE may be formed through various methods, such as a photolithography process. In a display apparatus 10 according to a present exemplary embodiment, the common electrode CE is disposed above the pixel electrode PE, but embodiments are not limited thereto. For example, the common electrode CE may be disposed under the pixel electrode PE.

A protection film may be disposed on the second insulating layer INL2 to protect the common electrode CE. An alignment layer may be disposed on the protection film.

The second substrate 200 includes a second base substrate SUB2, a black matrix BM, and a color filter CF. According to another embodiment, the black matrix BM and the color filter CF may be included in the first substrate 100.

The second base substrate SUB2 may be a transparent insulating substrate, such as a plastic substrate, a glass substrate, a quartz substrate, etc.

The black matrix BM is disposed on the second substrate SUB2 to correspond to a light blocking area of the first substrate 100. The light blocking area corresponds to an area in which the data line DL, the thin film transistor TFT, and the gate line GL are disposed. The pixel electrode PE is not disposed in the light blocking area, and thus liquid crystal molecules corresponding to the light blocking area may not be aligned, thereby causing light leakage. Thus, the black matrix BM may be disposed in the light blocking area to prevent light leakage from occurring. The black matrix BM may be formed before or after the color filter CF is formed. Alternatively, the black matrix BM and the color filter CF may be substantially simultaneously formed together. The black matrix BM may be formed by forming a light blocking layer that can absorb light and patterning the light blocking layer through a photolithography process, however embodiments are not limited thereto. For example, the black matrix BM may be formed by an inkjet method.

The color filter CF is disposed on the second base substrate SUB2 and imbues color to the light propagating through the liquid crystal layer LCL. The color filter CF may be formed by forming a color layer on the second base substrate SUB2 that provides a red color, a green color, a blue color, or other colors, and patterning the color layer through a photolithography process, but embodiments are not limited thereto. For example, the color filter CF may be formed by other methods, such as an inkjet method.

A planarization layer OC is disposed on the black matrix BM and the color filter CF. The planarization layer OC may planarize an upper surface of the second substrate 200.

An alignment layer is disposed on the planarization layer OC.

The liquid crystal layer LCL includes liquid crystal molecules that have a refractive index anisotropy. The liquid crystal molecules in the liquid crystal layer LCL between the first substrate 100 and the second substrate 200 rotate in a specific direction when an electric field is formed between the pixel electrode PE and the common electrode CE, to control light transmittance through the liquid crystal layer LCL.

Referring to FIGS. 1 to 3, the display apparatus 10 includes the spacer CS.

The spacer CS may maintain a gap between the first substrate 100 and the second substrate 200 and may absorbs external impacts received by the first and second substrates 100 and 200.

A plurality of spacers CS may be provided. For example, the spacer CS may include two or more spacers.

The spacer CS is disposed on the second substrate 200. As an example, the spacer CS is disposed on the planarization layer OC.

The spacer CS overlaps the black matrix BM. In addition, the spacer CS overlaps the non-display area NDA.

At least a portion of the spacer CS may overlap with a gate spacer part GCS on the first substrate 100. The gate spacer part GCS branches from the gate line GL and is spaced apart from the gate electrode GE. The gate spacer part GCS is spaced apart from the thin film transistor TFT and the contact hole CH. The gate spacer part GCS is spaced apart from the pixel electrode PE.

The gate spacer part GCS may have a multi-layer structure. The gate spacer part GCS may include one or more of nickel, chromium, molybdenum, aluminum, titanium, copper, tungsten, or alloys thereof.

The gate spacer part GCS may be formed from the same layer as the gate electrode GE. In FIGS. 2 and 3, the gate spacer part GCS has a rectangular shape, however, the shape of the gate spacer part GCS is not limited thereto. For example, the gate spacer part GCS may have other shapes, such as a circular shape, an oval shape, a triangular shape, a polygonal shape, etc.

In addition, part or all of the spacer CS may overlap the gate spacer part GCS.

At least a portion of the spacer CS may overlap with a source spacer part SCS disposed on the gate insulator GI. The source spacer part SCS is spaced apart from the drain electrode DE, the thin film transistor TFT and the contact hole CH. The source spacer part SCS is spaced apart from the pixel electrode PE.

The source spacer part SCS may have a multi-layer structure. The source spacer part SCS may include one or more of nickel, chromium, molybdenum, aluminum, titanium, copper, tungsten, or alloys thereof.

The source spacer part SCS is formed from the same layer as the source electrode SE. In FIGS. 2 and 3, the source spacer part SCS has a rectangular shape, but the shape of the source spacer part SCS is not limited thereto. For example, the source spacer part SCS may have other shapes, such as a circular shape, an oval shape, a triangular shape, a polygonal shape, etc.

FIG. 4 is a plan view that shows a pixel area PXL according to an exemplary embodiment of the present disclosure.

The pixel area PXL includes a red pixel area PXL_R, a green pixel area PXL_G, and a blue pixel area PXL_B. The red pixel area PXL_R may display a red color, the green pixel area PXL_G may display a green color, and the blue pixel area PXL_B may display a blue color.

The spacers CS are disposed in the red pixel area PXL_R and the blue pixel area PXL_B but not in the green pixel area PXL_G. The spacers CS overlap the black matrix BM.

Each spacer CS may include a first spacer CS1 and a second spacer CS2. The first and second spacers CS1 and CS2 are disposed on the second substrate 200, protrude toward the first substrate 100, and have different heights from each other. In a present exemplary embodiment, the first spacer CS1 may have a height h1 greater than a height h2 of the second spacer CS2.

In a present exemplary embodiment, each of the first spacer CS1 and the second spacer CS2 may have a truncated cone shape or a shape corresponding to a portion of the truncated cone, but the shapes of the first and second spacers CS1 and CS2 are not limited thereto. Hereinafter, the first spacer CS1 and the second spacer CS2 will be described as having a truncated cone shape or a shape corresponding to a portion of the truncated cone as a representative, non-limiting example.

The height h1 of the first spacer CS1 is defined by a cell gap between the first substrate 100 and the second substrate 200. Thus, the first spacer CS1 makes contact with the first substrate 100 and the second substrate 200 to maintain the cell gap.

The second spacer CS2 makes contact with the second substrate 200 and is spaced apart from the first substrate 100. The second spacer CS2 may have a compressive property that may increase durability against external impacts. When external impacts are received by the display apparatus 10, the first and second spacers CS1 and CS2 distribute the forces of the external impacts, to prevent defects from occurring in the display apparatus 10.

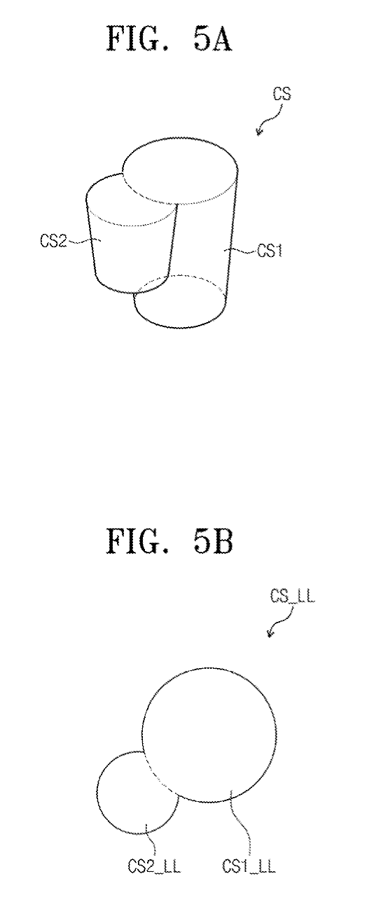

The spacer CS includes an upper surface in contact with the second substrate 200 and a lower surface CS_LL, shown in FIG. 5B, that faces the upper surface of the first substrate 100.

The lower surface CS_LL of the spacer CS in FIG. 5B has a shape in which a portion of a first circle and a portion of a second circle overlap each other. A line segment connecting a center of the first circle and a center of the second circle has a portion that overlaps the overlap area between the first and second circles with a length in a range from about 0.01 μm to about 5.0 μm. If the length of the line segment is less than about 0.01 μm, the first spacer CS1 may be spaced apart from the second spacer CS2, and foreign substances may cause defects to occurs in the display apparatus 10. If the length of the line segment exceeds about 5.0 μm, the overall surface area of the lower surface CS_LL, including that of the first spacer CS1 and the second spacer CS2, becomes small when viewed in a plan view. Therefore, when external impacts are received by the display apparatus 10, the external impacts may not be effectively distributed.

The spacer CS has a shape in which at least portions of the two different-sized truncated cones overlap. The lower surface CS_LL of the spacer CS in FIG. 5B includes a first lower surface CS1_LL in FIG. 5B that corresponds to a lower surface of the first spacer CS1 and a second lower surface CS2_LL in FIG. 5B that corresponds to a lower surface of the second spacer CS2. In a present exemplary embodiment, the size of the first lower surface CS1_LL in FIG. 5B may be greater than the size of the second lower surface CS2_LL in FIG. 5B.

FIG. 5A is a perspective view showing the spacer according to an exemplary embodiment of the present disclosure, and FIG. 5B is a plan view showing the lower surface of the spacer.

Referring to FIG. 5A, the shape of the second spacer CS2 corresponds to a portion of a truncated cone shape, and the shape of the first spacer CS1 is a truncated cone.

Referring to FIG. 5B, the first lower surface CS1_LL has a circular shape, and the second lower surface CS2_LL has a shape corresponding to a portion of a circle.

In a conventional display apparatus, since the spacer is not attached to the first substrate, an alignment layer disposed adjacent to the spacer may be scratched by the spacer when the external impacts are received by the display apparatus. Thus, the damaged alignment layer may not control the liquid crystal molecules, and thus light leakage may occur in an area corresponding to the damaged alignment layer.

However, according to a present exemplary embodiment of the present disclosure, the spacer overlaps one or both of the gate spacer part and the source spacer part, and thus the spacer may be prevented from making contact with the alignment layer except for the area where the spacer is disposed. Thus, the alignment layer may be protected from damage and light leakage from the display apparatus may be prevented, thereby improving the display quality of the display apparatus.

In addition, a conventional spacer is disposed to overlap the thin film transistor of the first substrate and the contact hole. As a result, a conventional spacer applies pressure to the thin film transistor and the contact hole, which may cause a malfunction of the display apparatus.

However, according to a present exemplary embodiment of the present disclosure, the spacer is disposed to overlap one or more of the gate spacer part and the source spacer part, which may protect the display apparatus from being mal-operated.

Although exemplary embodiments of the present disclosure have been described, it is understood that embodiments of the present disclosure should not be limited to these exemplary embodiments but that various changes and modifications can be made by one ordinary skilled in the art within the spirit and scope of the present disclosure as hereinafter claimed.

What is claimed is:

1. A display apparatus comprising:
a first substrate that includes a gate line extending in a first direction, a data line extending in a second direction substantially perpendicular to the first direction, and a gate electrode branched from the gate line;
a second substrate facing the first substrate;
a liquid crystal layer interposed between the first substrate and the second substrate; and
a spacer disposed on the second substrate and protruded toward the first substrate that includes a first spacer and a second spacer connected to each other that have different heights, wherein the first spacer makes contact with the first substrate and the second substrate, and the second spacer makes contact with the second substrate and is spaced above the first substrate.

2. The display apparatus of claim 1, wherein the first substrate further comprises:
a first base substrate;
a pixel electrode disposed on the first base substrate;
a common electrode that includes a plurality of slits, wherein at least a portion of the common electrode overlaps the pixel electrode;
a thin film transistor electrically connected to the gate line and the data line and configured to apply a signal to the pixel electrode; and
a gate spacer part disposed on a same layer as a gate electrode that branches from the gate line and is spaced apart from the gate electrode and the thin film transistor, wherein at least a portion of the spacer overlaps with the gate spacer part.

3. The display apparatus of claim 2, wherein the thin film transistor comprises:
the gate electrode disposed on the first base substrate;
a semiconductor pattern disposed on the gate electrode;
a source electrode disposed on the semiconductor pattern that partially overlaps the gate electrode; and
a drain electrode spaced apart from the source electrode, connected to the pixel electrode through a contact hole, that partially overlaps the gate electrode,
wherein the gate spacer part is spaced apart from the contact hole.

4. The display apparatus of claim 2, wherein the first substrate further comprises a display area in which an image is displayed and a non-display area in which no image is displayed, wherein the spacer overlaps the non-display area.

5. The display apparatus of claim 3, wherein the first substrate further comprises a source spacer part of which least a portion thereof overlaps the gate spacer part, wherein the source spacer part is disposed on a same layer as the source electrode.

6. The display apparatus of claim 1, wherein the second substrate comprises:
a second base substrate;
a black matrix disposed on the second base substrate that overlaps the gate line and the data line;
a color filter disposed on the second base substrate that is configured to display color images; and
a planarization layer disposed on the black matrix and the color filter.

7. The display apparatus of claim 6, wherein the spacer is disposed on the planarization layer and overlaps the black matrix.

8. The display apparatus of claim 1, wherein a plurality of spacers are provided.

9. The display apparatus of claim 8, wherein the first substrate further comprises a plurality of gate lines and a plurality of data lines, and a plurality of pixel areas defined by the gate lines and the data lines,
wherein each pixel area comprises a red pixel area configured to display a red color, a green pixel area configured to display a green color, and a blue pixel area configured to display a blue color, and the spacer is disposed in the red pixel area and the blue pixel area.

10. The display apparatus of claim 1, wherein the first spacer has a height greater than a height of the second spacer.

11. The display apparatus of claim I, wherein the spacer comprises:
an upper surface in contact with a lower surface of the second substrate; and
a lower surface that faces an upper surface of the first substrate, wherein the lower surface has a shape defined by a first circle and a second circle that partially overlaps the first circle.

12. The display apparatus of claim 11, wherein the lower surface comprises:
a first lower surface corresponding to a lower surface of the first spacer; and
a second lower surface corresponding to a lower surface of the second spacer,
wherein the first lower surface has a circular shape, the second lower surface has a shape corresponding to a portion of a circle, and the first lower surface has an area greater than an area of the second lower surface.

13. A display apparatus comprising:
a first substrate that includes a plurality of gate lines extending in a first direction and a plurality of data lines extending in a second direction substantially perpendicular to the first direction;
a second substrate facing the first substrate; and
a plurality of spacers disposed on the second substrate and protruded toward the first substrate, wherein a spacer comprises:
a first spacer and a second spacer connected to each other;
an upper surface in contact with a lower surface of the second substrate; and
a lower surface that faces an upper surface of the first substrate, wherein the lower surface has a shape defined by a first circle and a second circle that partially overlaps the first circle.

14. The display apparatus of claim 13, wherein the first substrate further comprises:
a first base substrate;
a pixel electrode disposed on the first base substrate;
a common electrode that includes a plurality of slits, wherein at least a portion of the common electrode overlaps the pixel electrode;
a thin film transistor electrically connected to the gate line and the data line and configured to apply a signal to the pixel electrode;
a gate spacer part disposed on a same layer as the gate line and is spaced apart from the gate line and the thin film transistor, wherein at least a portion of the spacer overlaps with the gate spacer part; and
a source spacer part of which at least a portion thereof overlaps the gate spacer part, wherein the source spacer part is disposed on a same layer as the data line.

15. The display apparatus of claim 14, further comprising a liquid crystal layer interposed between the first substrate and the second substrate.

16. The display apparatus of claim 14, wherein the first substrate further comprises a display area in which an image is displayed and a non-display area in which no image is displayed, wherein each spacer overlaps the non-display area.

17. The display apparatus of claim 13, wherein the second substrate comprises:
a second base substrate;
a black matrix disposed on the second base substrate that overlaps the gate line and the data line;
a color filter disposed on the second base substrate that is configured to display color images; and
a planarization layer disposed on the black matrix and the color filter,
wherein each spacer is disposed on the planarization layer and overlaps the black matrix.

18. The display apparatus of claim 13, wherein the first spacer has a height greater than a height of the second spacer, wherein the first spacer makes contact with the first substrate and the second substrate, and the second spacer makes contact with the second substrate and is spaced above the first substrate.

19. The display apparatus of claim 13, wherein the lower surface comprises:
a first lower surface corresponding to a lower surface of the first spacer; and
a second lower surface corresponding to a lower surface of the second spacer,
wherein the first lower surface has a circular shape, the second lower surface has a shape corresponding to a portion of a circle, and the first lower surface has an area greater than an area of the second lower surface.

20. The display apparatus of claim 13, further comprising a plurality of pixel areas defined by the gate lines and the data lines, wherein each pixel area comprises a red pixel area configured to display a red color, a green pixel area configured to display a green color, and a blue pixel area configured to display a blue color, and the spacer is disposed in the red pixel area and the blue pixel area.
